(19) United States
(12) Patent Application Publication
(10) Pub. No.: US 2026/0282798 A1
(43) Pub. Date: Sep. 17, 2026

(54) SUBSTRATE PROCESSING APPARATUS, PROCESSING LIQUID SUPPLY DEVICE, SUBSTRATE PROCESSING METHOD AND PROCESSING LIQUID SUPPLY METHOD

(71) Applicant: SCREEN HOLDINGS CO., LTD., Kyoto (JP)

(72) Inventor: Tetsuya WATANABE, Kyoto-shi (JP)

(21) Appl. No.: 19/561,905

(22) Filed: Mar. 10, 2026

(30) Foreign Application Priority Data
Mar. 14, 2025 (JP) 2025-041921

(51) Int. Cl. H10P 72/00

(52) U.S. Cl. CPC H10P 72/0424

(57) ABSTRACT

A substrate processing apparatus includes a plurality of chambers and a processing liquid supply device that supplies a processing liquid to each chamber. The processing liquid supply device includes a storage tank provided below the plurality of chambers and a circulation pipe that causes the processing liquid in the storage tank to circulate. Further, the processing liquid supply device includes a temperature adjuster, a plurality of chamber supply pipes and a chamber collection pipe. The temperature adjuster adjusts a temperature of the circulating processing liquid to a target temperature. Each chamber supply pipe guides the circulating processing liquid to a corresponding chamber. The chamber collection pipe returns the processing liquid used in each chamber to the storage tank. A branch pipe is provided to connect part of the circulation pipe to part of the chamber collection pipe. An adjusting valve is provided in the branch pipe.

### BACKGROUND

### Technical Field

The present disclosure relates to a substrate processing apparatus and a substrate processing method for executing a process using a processing liquid on a plurality of substrates. Further, the present disclosure relates to a processing liquid supply device and a processing liquid supply method for supplying a processing liquid to a chamber.

### Description of Related Art

A substrate processing apparatus is used to execute various processes on a substrate such as a semiconductor substrate, a substrate for an FPD (Flat Panel Display) that is used for a liquid crystal display device, an organic EL (Electroluminescence) display device or the like, a substrate for an optical disc, a substrate for a magnetic disc, a substrate for a magneto-optical disc, a substrate for a photomask, a ceramic substrate or a substrate for a solar cell.

As one example of a substrate processing apparatus, a substrate processing apparatus that processes a substrate using a chemical liquid is described in JP 2011-61034 A. The substrate processing apparatus includes a processing unit (chamber) and a chemical liquid supply unit (processing liquid supply device). The chemical liquid supply unit supplies the chemical liquid to the processing unit. In the processing unit, the substrate is processed using the chemical liquid supplied from the chemical liquid supply unit.

### SUMMARY

The chemical liquid supply unit described in JP 2011-61034 A includes a chemical liquid tank, a chemical liquid supply pipe, a circulation pipe and a collection pipe. The chemical tank stores a predetermined amount of chemical liquid. The chemical liquid supply pipe extends from the chemical liquid tank to the processing unit, and is provided with a pump and a filter. The circulation pipe connects a portion of the chemical liquid supply pipe downstream of the pump and the filter to the chemical liquid tank. The collection pipe connects the processing unit to the chemical liquid tank. The chemical liquid supply pipe and the circulation pipe are provided with valves.

In the chemical liquid supply unit, the pump works, and the state of each valve is controlled. In a case in which the chemical liquid is not supplied to the processing unit, the chemical liquid stored in the chemical liquid tank circulates through the chemical liquid supply pipe and the circulation pipe. At this time, the chemical liquid repeatedly passes through the filter, so that degradation of cleanliness of the chemical liquid in the chemical liquid tank is suppressed. In a case in which the chemical liquid is supplied to the processing unit, the chemical liquid stored in the chemical liquid tank is supplied to the processing unit through the chemical liquid supply pipe. In the processing unit, the chemical liquid used in a process for the substrate is collected by a cup. The collected chemical liquid is returned to the chemical liquid tank through the collection pipe. This can reduce the consumption of the chemical liquid.

Meanwhile, depending on the contents of substrate processing, the temperature of the chemical liquid supplied to the substrate may be required to be set to a specific temperature (hereinafter referred to as a target temperature). In this case, it is conceivable to provide a temperature adjusting device (a heater, a heat exchanger or the like) for adjusting the temperature of the chemical liquid in any of the chemical liquid tank, the chemical liquid supply pipe and the circulation pipe, for example, and cause the chemical liquid in the chemical liquid tank to circulate.

However, in this case, when the temperature of the chemical liquid returned from the processing unit to the chemical liquid tank during the process for the substrate largely deviates from the target temperature, large variations in temperature of the chemical liquid in the chemical liquid tank are generated. The large variations in temperature of the chemical liquid in the chemical liquid tank may cause variations in temperature of the processing liquid supplied to the substrate, and may degrade credibility of the processing liquid supplied to the chamber.

An object of the present disclosure is to provide a substrate processing apparatus, a processing liquid supply device, a substrate processing method and a processing liquid supply method that improve credibility of a processing liquid supplied to a chamber.

A substrate processing apparatus according to one aspect of the present disclosure includes a first chamber that executes a process on a substrate using a processing liquid, a tank that is provided below the first chamber and stores the processing liquid, a circulation flow path that causes the processing liquid in the tank to circulate between inside of the tank and outside of the tank, a temperature adjuster that adjusts, to a predetermined target temperature, a temperature of the processing liquid that is made to circulate by the circulation flow path, a first chamber supply flow path that connects the circulation flow path to the first chamber and guides the processing liquid flowing through the circulation flow path to the first chamber, a chamber collection flow path that connects the tank to the first chamber and returns the processing liquid used in the first chamber to the tank, a branch flow path that connects the circulation flow path to the chamber collection flow path and guides the processing liquid flowing through the circulation flow path to the chamber collection flow path, and a flow-rate adjuster that is provided in the branch flow path and adjusts a flow rate of the processing liquid flowing through the branch flow path.

A processing liquid supply device according to another aspect of the present disclosure that supplies a processing liquid to a chamber in which a process is executed on a substrate using the processing liquid, includes a tank that is provided below the chamber and stores the processing liquid, a circulation flow path that causes the processing liquid in the tank to circulate between inside of the tank and outside of the tank, a temperature adjuster that adjusts, to a predetermined target temperature, a temperature of the processing liquid that is made to circulate by the circulation flow path, a chamber supply flow path that connects the circulation flow path to the chamber and guides the processing liquid flowing through the circulation flow path to the chamber, a chamber collection flow path that connects the tank to the chamber and returns the processing liquid used in the chamber to the tank, a branch flow path that connects the circulation flow path to the chamber collection flow path and guides the processing liquid flowing through the circulation flow path to the chamber collection flow path, and a flow-rate adjuster that is provided in the branch flow path and adjusts a flow rate of the processing liquid flowing through the branch flow path.

A substrate processing method according to yet another aspect of the present disclosure of processing a substrate using a substrate processing apparatus, wherein the substrate processing apparatus further includes a chamber that executes a process on the substrate using a processing liquid, a tank that is provided below the chamber and stores the processing liquid, a circulation flow path that causes the processing liquid in the tank to circulate between inside of the tank and outside of the tank, a chamber supply flow path that connects the circulation flow path to the chamber and guides the processing liquid flowing through the circulation flow path to the chamber, and a chamber collection flow path that connects the tank to the chamber and returns the processing liquid used in the chamber to the tank, and the substrate processing method includes adjusting, to a predetermined target temperature, a temperature of the processing liquid that is made to circulate by the circulation flow path, guiding the processing liquid flowing through the circulation flow path to the chamber collection flow path using a branch flow path, the branch flow path connecting the circulation flow path to the chamber collection flow path, and adjusting a flow rate of the processing liquid flowing through the branch flow path.

A processing liquid supply method according to yet another aspect of the present disclosure of supplying a processing liquid to a chamber in which a process is executed on a substrate using a processing liquid supply device, wherein the processing liquid supply device includes a tank that is provided below the chamber and stores the processing liquid, a circulation flow path that causes the processing liquid in the tank to circulate between inside of the tank and outside of the tank, a chamber supply flow path that connects the circulation flow path to the chamber and guides the processing liquid flowing through the circulation flow path to the chamber, and a chamber collection flow path that connects the tank to the chamber and returns the processing liquid used in the chamber to the tank, and the processing liquid supply method includes adjusting, to a predetermined target temperature, a temperature of the processing liquid that is made to circulate by the circulation flow path, guiding the processing liquid flowing through the circulation flow path to the chamber collection flow path using a branch flow path, the branch flow path connecting the circulation flow path to the chamber collection flow path, and adjusting a flow rate of the processing liquid flowing through the branch flow path.

With the present disclosure, it is possible to improve credibility of the processing liquid supplied to the chamber.

Other features, elements, characteristics, and advantages of the present disclosure will become more apparent from the following description of preferred embodiments of the present disclosure with reference to the attached drawings.

### BRIEF DESCRIPTION OF THE DRAWING

FIG. 1 is a schematic configuration diagram of a substrate processing apparatus according to one embodiment of the present disclosure;

FIG. 2 is a diagram for explaining the state of a processing liquid flowing through each pipe in the substrate processing apparatus of FIG. 1;

FIG. 3 is a block diagram showing the configuration of a control system of the substrate processing apparatus of FIG. 1;

FIG. 4 is a flowchart showing one example of a liquid supply process executed in the substrate processing apparatus 1 according to the one embodiment;

FIG. 5 is a schematic plan view showing one example of a substrate processing system including the plurality of substrate processing apparatuses 1 of FIG. 1;

FIG. 6 is a diagram showing a first configuration example of a substrate processing apparatus 1 according to another embodiment;

FIG. 7 is a diagram showing a second configuration example of the substrate processing apparatus 1 according to the other embodiment;

FIG. 8 is a diagram showing a third configuration example of the substrate processing apparatus 1 according to the other embodiment;

FIG. 9 is a diagram for explaining one example of the configuration of a chamber collection pipe according to the other embodiment.

### DETAILED DESCRIPTION

A substrate processing apparatus, a processing liquid supply device, a substrate processing method and a processing liquid supply method according to one embodiment of the present disclosure will be described below with reference to the drawings. In the following description, a substrate refers to a substrate for a Flat Panel Display (FPD) that is used for a liquid crystal display device, an organic Electroluminescence (EL) display device or the like, a semiconductor substrate, a substrate for an optical disc, a substrate for a magnetic disc, a substrate for a magneto-optical disc, a substrate for a photomask, a ceramic substrate, a substrate for a solar cell or the like.

### 1. Configuration of Substrate Processing Apparatus

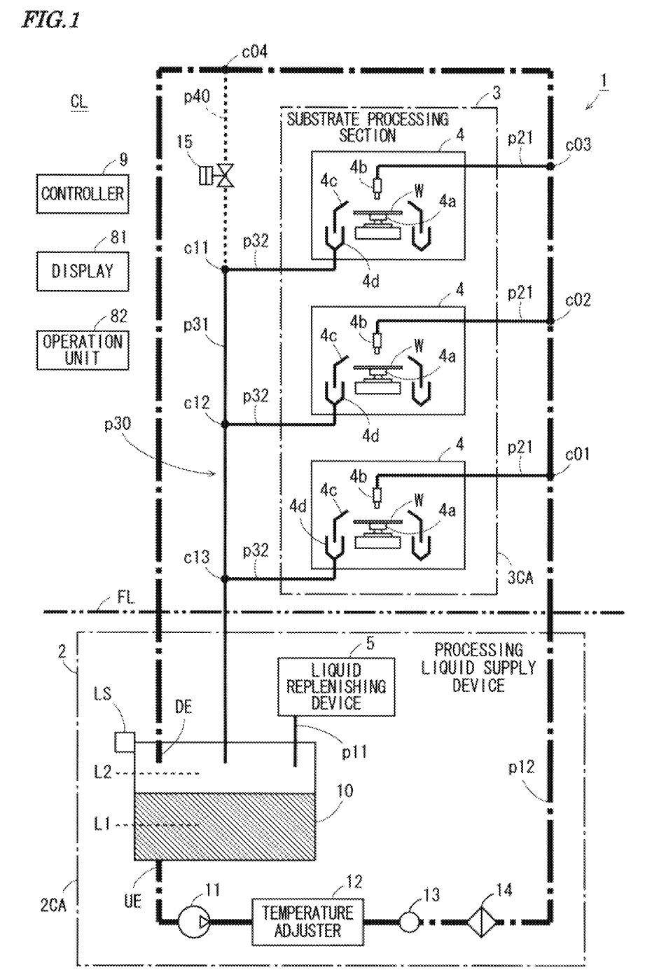

FIG. 1 is a schematic configuration diagram of the substrate processing apparatus according to the one embodiment of the present disclosure. In the substrate processing apparatus 1 according to the present embodiment, a process is executed on a substrate W using a processing liquid. As shown in FIG. 1, the substrate processing apparatus 1 is provided in a clean room CL, and includes a processing liquid supply device 2, a substrate processing section 3, a controller 9, a display 81 and an operation unit 82. In the clean room CL, a floor portion FL formed of a grating is provided. Thus, an upper region and a lower region are formed in the clean room CL. In FIG. 1 and subsequent diagrams, the floor portion FL is indicated by the thick two-dots and dash line.

The processing liquid supply device 2 includes a supply device casing 2CA that accommodates a large portion of a plurality of constituent elements of the processing liquid supply device 2. Further, the substrate processing section 3 includes a processing section casing 3CA that accommodates a large portion of the plurality of constituent elements of the substrate processing section 3. In the example of FIG. 1, the supply device casing 2CA is arranged in the lower region, and the processing section casing 3CA is arranged in the upper region. Details of the constituent elements accommodated in the supply device casing 2CA and the processing section casing 3CA will be described below.

In the present embodiment, the processing liquid used in the process for the substrate W is a chemical liquid for etching a film such as a silicon oxide film, a silicon nitride film or a titanium nitride film formed on the substrate W.

Examples of the chemical liquid include hydrofluoric acid (HF), buffered hydrofluoric acid (BHF), dilute hydrofluoric acid (DHF), a mixture of sulfuric acid and hydrogen peroxide (SPM), a mixture of ammonium water and hydrogen peroxide (SC1), a mixture of hydrochloric acid and hydrogen peroxide (SC2), diluted ammonium hydroxide (dNH₄OH) and tetramethylammonium hydroxide (TMAH).

In the process for the substrate W, the temperature of the processing liquid affects a processing amount (an etching amount, for example). Therefore, a target temperature corresponding to the processing contents is defined in regard to the processing liquid supplied to the substrate W. The target temperature is an ideal temperature of the processing liquid supplied to the substrate W, and is defined by a user of the substrate processing apparatus 1, for example.

The processing liquid supply device 2 stores a certain amount of the processing liquid in a storage tank 10, described below, and adjusts the temperature of the processing liquid to the target temperature. Further, the processing liquid supply device 2 supplies the temperature-adjusted processing liquid to the substrate processing section 3.

The substrate processing section 3 includes a plurality (three in the present example) of chambers 4. The three chambers 4 of the present example are accommodated in the processing section casing 3CA in a stacked manner. Each chamber 4 is provided with a spin chuck 4a, a nozzle 4b, a cup 4c and a collector 4d. The spin chuck 4a is configured to be capable of holding the substrate W to be processed. Further, the spin chuck 4a is driven by a driving device (not shown) (an electric motor, for example) to rotate while holding the substrate W. Thus, the substrate W held by the spin chuck 4a rotates.

The nozzle 4b discharges, to the substrate W held and rotated by the spin chuck 4a, part of the processing liquid supplied from the processing liquid supply device 2 to the substrate processing section 3. Thus, the obverse surface (the upper surface in the present example) of the substrate W is processed. The cup 4c is provided so as to surround the substrate W held by the spin chuck 4a, and receives the processing liquid splashing from the substrate W during the process for the substrate W. The collector 4d collects the processing liquid that has been received by the cup 4c. At least part of the processing liquid collected by the collector 4d is returned to the processing liquid supply device 2.

The controller 9 controls the work of each component of the processing liquid supply device 2 and the substrate processing section 3. Details of the controller 9 will be described below. The display 81 is formed of a liquid crystal display device or an organic EL display device, for example. An example of information displayed on the display 81 will be described below. The operation unit 82 includes a keyboard and a pointing device, for example, and is configured to be operable by the user. The user can input various information to the substrate processing apparatus 1 by operating the operation unit 82.

### 2. Configuration and Basic Work of Processing Liquid Supply Device 2

In addition to the above-mentioned supply device casing 2CA, the processing liquid supply device 2 includes a liquid replenishing device 5, the storage tank 10, a pump 11, a temperature adjuster 12, a thermal sensor 13, a filter 14, an adjusting valve 15, a replenishing pipe p11, a circulation pipe p12, a plurality of chamber supply pipes p21, a chamber collection pipe p30 and a branch pipe p40. In the supply device casing 2CA of FIG. 1, among the plurality of above-mentioned constituent elements, the liquid replenishing device 5, the storage tank 10, the pump 11, the temperature adjuster 12, the thermal sensor 13 and the filter 14 are accommodated.

In a factory in which the clean room CL is provided, a supply source of the processing liquid used for processing the substrate W is provided as a utility facility. The liquid replenishing device 5 includes fluid-related elements such as a pipe, a joint and a valve, and is connected to the supply source (not shown) of the processing liquid. The liquid replenishing device 5 may include a pump as part of the fluid-related elements. The upstream end of the replenishing pipe p11 is connected to the liquid replenishing device 5. In FIG. 1, the replenishment pipe p11 is indicated by the thick solid line. The downstream end of the replenishing pipe p11 is arranged in the storage tank 10. The liquid replenishing device 5 is configured to be capable of supplying a processing liquid (new processing liquid) of the supply source (not shown) to the storage tank 10 (replenishing the storage tank 10 with a processing liquid (new processing liquid) through the replenishing pipe p11.

The storage tank 10 is configured to be capable of storing a certain amount of the processing liquid. A liquid level sensor LS is attached to the storage tank 10. The liquid level sensor LS detects a liquid level (height of liquid level) of the processing liquid stored in the storage tank 10. Further, the liquid level sensor LS outputs a liquid level signal indicating the detected liquid level to the controller 9. As the liquid level sensor LS, a capacitance-type liquid level sensor, an optical-type liquid level sensor or an ultrasonic-type liquid level sensor can be used, for example.

The circulation pipe p12 has an upstream end UE and a downstream end DE. In FIG. 1, the circulation pipe p12 is indicated by the thick one-dot and dash lines. The upstream end UE of the circulation pipe p12 is connected to a bottom portion of the storage tank 10. The circulation pipe p12 extends from the bottom portion of the storage tank 10 and is drawn out to a space above the 2CA of the supply device casing 2CA.

The portion of the circulation pipe p12 drawn out from the supply device casing 2CA penetrates the floor portion FL, passes through the vicinity of the substrate processing section 3 in the upper region of the clean room CL, penetrates the floor portion FL again, and extends into the supply device casing 2CA. The downstream end DE of the circulation pipe p12 is arranged in the storage tank 10.

In the supply device casing 2CA, the pump 11 is provided in the vicinity of the upstream end UE of the circulation pipe p12. Further, in the circulation pipe p12, the temperature adjuster 12, the thermal sensor 13 and the filter 14 are provided downstream of the pump 11 in this order.

The pump 11 sucks the processing liquid stored in the storage tank 10, and pumps the sucked processing liquid toward the downstream end DE of the circulation pipe p12. The temperature adjuster 12 adjusts the temperature of the processing liquid flowing through the circulation pipe p12 such that the temperature of the processing liquid is maintained at the target temperature or is brought close to the target temperature. Therefore, in a case in which the target temperature is higher than a temperature in the factory, the temperature adjuster 12 includes a heating device such as a heater. On the other hand, in a case in which the target temperature is lower than a temperature in the factory, the temperature adjuster 12 includes a cooling device such as a cooling fan.

In addition to the above-mentioned example, the temperature adjuster 12 may be configured to be capable of heating the processing liquid and cooling the processing liquid by including a Peltier element or a heat exchanger. The larger the adjustable temperature range of the processing liquid, the higher the degree of freedom in regard to a process for the substrate W. For example, an etching amount can be adjusted over a wide range.

The thermal sensor 13 detects a temperature of the processing liquid flowing downstream of the temperature adjuster 12 and flowing in the vicinity of the temperature adjuster 12 in the circulation pipe p12. Further, the thermal sensor 13 outputs a temperature signal indicating the detected temperature of the processing liquid to the controller 9. The filter 14 filters the processing liquid to capture precipitates, contaminants and the like in the processing liquid.

In the upper region of the clean room CL, a plurality of chamber supply pipesp12 are connected to a plurality of portions of the circulation pipep12. In FIG. 1, the plurality of chamber supply pipes p21 are indicated by the thick solid lines. The plurality (three in the present example) of chamber supply pipes p21 respectively correspond to the plurality of chambers 4 of the substrate processing section 3, and connect a plurality of respective portions of the circulation pipep12 to the respective nozzles 4b of the plurality of chambers 4.

Here, in the circulation pipe p12, three portions (branch points) to which the three chamber supply pipes p21 are connected are referred to as a first portion c01, a second portion c02 and a third portion c03. The first portionc01, the second portion c02 and the third portion c03 are arranged in this order from an upstream position to a downstream position of the circulation pipe p12.

A plurality of valves (not shown) are respectively provided in the plurality of chamber supply pipes p21. By switching of the open-close states of the plurality of valves, part of the processing liquid flowing through the circulation pipe p12 is selectively guided to the nozzle 4b of at least one of the plurality of chambers 4.

The chamber collection pipe p30 includes a main collection pipe p31 and a plurality of sub-collection pipes p32. In FIG. 1, the chamber collection pipe p30 is indicated by the thick solid line. The main collection pipe p31 is provided so as to penetrate the floor portion FL and extend in an upward-and-downward direction. The lower end portion of the main collection pipep31 is arranged in the storage tank 10. The upper end portion of the main collection pipe p31 is located in the vicinity of the chamber 4 located at the highest position among the plurality of chambers 4.

The plurality of sub-collection pipesp32 are connected to a plurality of portions of the main collection pipep31. The plurality (three in the present example) of sub-collection pipesp32 respectively correspond to the plurality of chambers 4 of the substrate processing section 3, and connect the plurality of respective portions of the main collection pipe p31 to the respective collectors 4d of the plurality of chambers 4.

Here, in the main collection pipe p31 of the chamber collection pipe p30, three portions (branch points) to which the three sub-collection pipes p32 are connected are referred to as a first portion c11, a second portion c12 and a third portion c13. The first portion c11, the second portion c12 and the third portion c13 are arranged in this order from an upward position to a downward position.

The main collection pipep31 and the plurality of sub-collection pipesp32 are not provided with a structure (such as a valve) that restricts a flow of liquid flowing through the pipes. Therefore, in a case in which the substrate W is processed in the plurality of chambers 4, the used processing liquid is guided from the plurality of chambers 4 to the main collection pipe p31 through the plurality of sub-collection pipesp32. The processing liquid guided to each portion (c11, c12, c13) of the main collection pipe p31 flows downwardly in the main collection pipe p31 to be returned to the storage tank 10.

The branch pipe p40 is provided in the upper region of the clean room CL. In FIG. 1, the branch pipe p40 is indicated by the thick dotted line. The branch pipe p40 is provided so as to connect one portion of the circulation pipep12 to the chamber collection pipe p30. Specifically, one end portion (upstream end) of the branch pipe p40 is connected to a fourth portionc04 of the circulation pipe p12, with the fourth portion c04 being located downstream of the first portion c01, the second portion c02 and the third portion c03 and above the main collection pipe p31. Further, the other end (downstream end) of the branch pipep40 is connected to the first portion c11 of the main collection pipe p31.

The adjusting valve 15 is provided in the branch pipep40. The adjusting valve 15 is a motor needle valve, for example, and adjusts the flow rate of the processing liquid flowing through the branch pipe p40 based on the control of the controller 9.

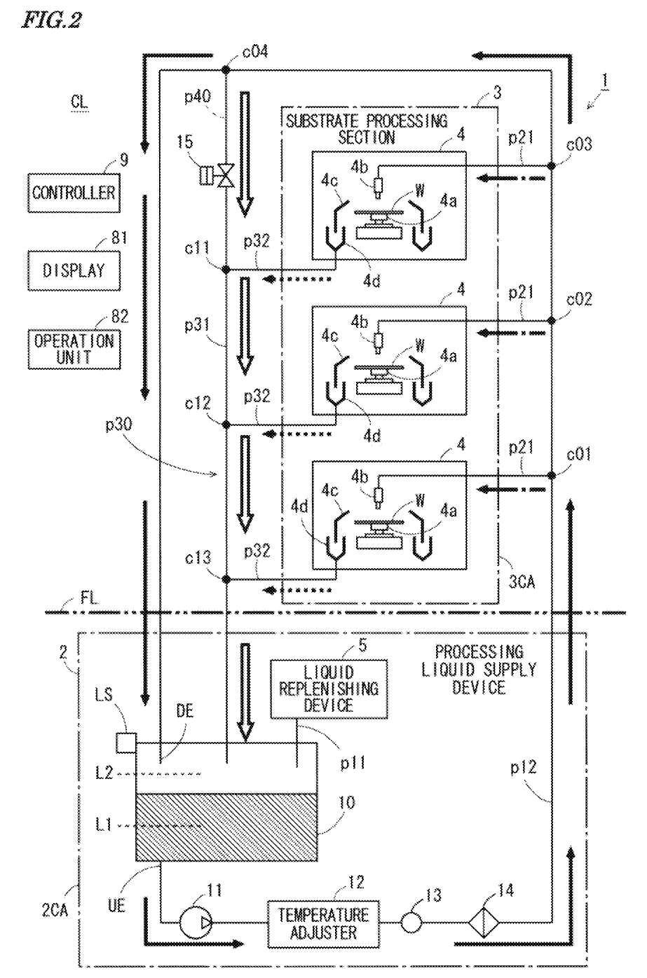

FIG. 2 is a diagram for explaining the state of the processing liquid flowing through each pipe in the substrate processing apparatus 1 of FIG. 1. First, suppose that the power of the substrate processing apparatus 1 is turned on. In this case, the pump 11 works. Thus, part of the processing liquid in the storage tank 10 flows into the upstream end UE of the circulation pipe p12. Further, as indicated by the thick solid arrow in FIG. 2, the processing liquid that has flowed into the upstream end UE flows through the circulation pipe p12 and is returned to the storage tank 10. Thus, the processing liquid in the storage tank 10 circulates between the inside of the storage tank 10 and the outside of the storage tank 10.

During this circulation of the processing liquid, the temperature of the processing liquid is maintained at the target temperature or brought close to the target temperature by the temperature adjuster 12. Further, precipitates or contaminants contained in the processing liquid are removed by the filter 14.

Here, in the substrate processing apparatus 1 according to the present embodiment, when the power is turned on, a degree of opening (an opening) of the adjusting valve 15 is adjusted such that part of the processing liquid flowing through the circulation pipe p12 flows to the main collection pipe p30 of the chamber collection pipe p30. In FIG. 2, the state of part of the processing liquid that flows through the circulation pipe p12 and flows into the storage tank 10 through the branch pipe p40 and the main collection pipe p31 is indicated by the thick outlined arrow.

The temperature of the processing liquid detected by the thermal sensor 13 is maintained in a certain range including the target temperature, so that the substrate W is processed in the plurality of chambers 4. In this case, as indicated by the thick one-dot and dash arrow in FIG. 2, part of the processing liquid flowing through the circulation pipe p12 is supplied to each chamber 4. Further, as indicated by the thick dotted arrow in FIG. 2, the processing liquid used in each chamber 4 flows to the main collection pipe p31 through the sub-collection pipe p32.

As described above, when the power of the substrate processing apparatus 1 is turned on, the processing liquid flows from the branch pipe p40 to the main collection pipe p31. Thus, the processing liquid flowing from each sub-collection pipe p32 into the main collection pipe p31 mixes with the processing liquid flowing from the branch pipe p40, and is sent to the storage tank 10. Thus, the temperature of the main collection pipe p31 is maintained in the certain range including the target temperature. Further, the temperature of the branch pipe p40 is maintained in the certain range including the target temperature.

In the substrate processing apparatus 1 according to the present embodiment, an opening to which the opening of the adjusting valve 15 is to be adjusted when the power of the substrate processing apparatus 1 is in an ON state is set. This opening is referred to as a target branch opening. The target branch opening is defined such that the main collection pipe p40 is not filled with the processing liquid in a case in which the processing liquid flows from the branch pipe p40 to the main collection pipe p31, regardless of from which chamber 4 of the plurality of chambers 4 the processing liquid is collected. That is, the target branch opening is defined such that all portions of the main collection pipe p31 are not filled with the processing liquid even in a case in which the processing liquid flows to all of the sub-collection pipes p32 of the chamber collection pipe p30 because the processing liquid is collected from all of the chambers 4 of the substrate processing section 3 at the same time.

### 3. Processing Liquid Replenishing Function

In the processing liquid supply device 2 having the above-mentioned configuration, a large portion of the processing liquid flowing through the circulation pipe p12 is returned to the storage tank 10. However, all of the processing liquid flowing through the circulation pipe p12 is not returned to the storage tank 10. This is because part of the processing liquid used in the process for the substrate W is discarded to the outside of the substrate processing apparatus 1 through a liquid drain system (not shown). Therefore, when a new processing liquid is not supplied from the liquid replenishing device 5 to the storage tank 10, the liquid level of the processing liquid stored in the storage tank 10 is lowered each time a process is executed in the substrate processing section 3.

As such, the processing liquid supply device 2 according to the present embodiment is provided with a processing liquid replenishing function of suitably replenishing the storage tank 10 with the processing liquid. With the processing liquid replenishing function, the storage tank 10 is replenished with the processing liquid supplied from the liquid replenishing device 5 based on a liquid level of the processing liquid detected by the liquid level sensor LS and a plurality of liquid levels preset in the storage tank 10.

In the storage tank 10, a lower limit level L1 and a prescribed level L2 are set as the plurality of liquid levels. The lower limit level L1 corresponds to an amount of the processing liquid considered to be minimally required for supplying the processing liquid to the substrate processing section 3, and is used to determine whether to start replenishment with the processing liquid by the liquid replenishing device 5. On the other hand, the prescribed level L2 is higher than the lower limit level L1, corresponds to an amount of the processing liquid considered to be sufficient for supplying the processing liquid to the substrate processing section 3, and corresponds to an amount of the processing liquid considered not to overflow from the storage tank 10. The prescribed level L2 is used to determine whether to stop replenishment during replenishment with the processing liquid by the liquid replenishing device 5.

An example of replenishment of the storage tank 10 with a new processing liquid based on the lower limit level L1 and the prescribed level L2 will be described. First, suppose that the liquid level of the processing liquid stored in the storage tank 10 is higher than the lower limit level L1 and lower than the prescribed level L2. Suppose that a new processing liquid is not supplied from the liquid replenishing device 5 to the storage tank 10 in this state.

Next, suppose that the liquid level of the processing liquid in the storage tank 10 is lowered by execution of a plurality of processes in the substrate processing section 3, and the liquid level of the processing liquid reaches the lower limit level L1. In this case, at a point in time at which the liquid level of the processing liquid reaches the lower limit level L1, the supply of the new processing liquid from the liquid replenishing device 5 to the storage tank 10 is started.

When the supply of the new processing liquid is started, the liquid level of the processing liquid gradually rises. In a period during which the liquid level of the processing liquid is higher than the lower limit level L1 and lower than the prescribed level L2, the storage tank 10 is continuously replenished with the processing liquid supplied from the liquid replenishing device 5. Thereafter, suppose that the liquid level of the processing liquid reaches the prescribed level L2. At this time, the supply of the new processing liquid from the liquid replenishing device 5 to the storage tank 10 is stopped.

In this manner, with the processing liquid replenishing function of the substrate processing apparatus 1, the storage tank 10 is replenished with the processing liquid at an appropriate point in time. This prevents the processing liquid in the storage tank 10 from being depleted.

### 4. Control System of Substrate Processing Apparatus

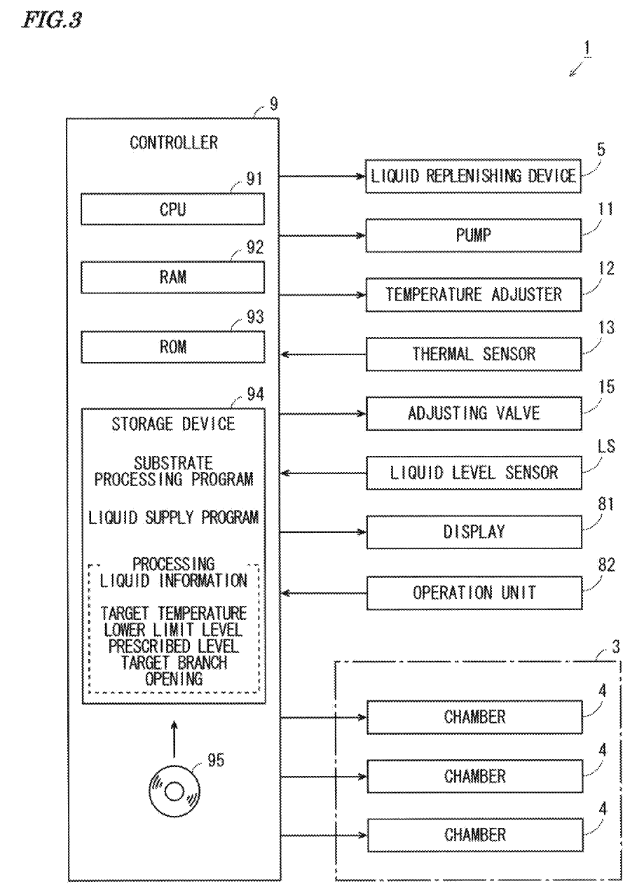

A control system of the substrate processing apparatus 1 will be described together with the configuration of the controller 9 of FIG. 1. FIG. 3 is a block diagram showing the configuration of a control system of the substrate processing apparatus 1 of FIG. 1. As shown in FIG. 3, the controller 9 includes a Central Processing Unit (CPU) 91, a Random Access Memory (RAM) 92, a Read Only Memory (ROM) 93 and a storage device 94.

The RAM 92 is used as a work area for the CPU 91. A system program is stored in the ROM 93. The storage device 94 includes a storage medium such as a hard disc or a semiconductor memory, and stores a substrate processing program for executing a process on a substrate in the substrate processing section 3 and a liquid supply program for supplying the processing liquid to the plurality of chambers 4 in the processing liquid supply device 2. Further, the storage device 94 stores processing liquid information. The processing liquid information is related to the processing liquid, and includes the target temperature of the processing liquid, the lower limit level L1, the prescribed level L2 and the target branch opening.

The substrate processing program and the liquid supply program may be provided in the state of being stored in a recording medium such as a CD-ROM 95 and installed in the ROM 93 or the storage device 94. Alternatively, the substrate processing program and the liquid supply program may be distributed from a server outside of the substrate processing apparatus 1 through a communication network and installed in the ROM 93 or the storage device 94.

When the CPU 91 executes the liquid supply program, a necessary amount of the processing liquid is supplied from the processing liquid supply device 2 to the substrate processing section 3. Further, when the CPU 91 executes the substrate processing program, the work of each component of the substrate processing section 3 is controlled, and a process is executed using the processing liquid in each of the plurality of chambers 4.

The work of the controller 9 during execution of the substrate processing program and the liquid supply program will be described. The controller 9 receives a liquid level signal output from the liquid level sensor LS. Thus, the controller 9 controls the liquid replenishing device 5 based on a detection result of the liquid level sensor LS and the processing liquid information.

Specifically, in a case in which the liquid level of the processing liquid in the storage tank 10 is lowered to the lower limit level L1, the controller 9 causes the liquid replenishing device 5 to work and replenish the storage tank 10 with the processing liquid. Further, in a case in which the liquid level of the processing liquid in the storage tank 10 rises to the prescribed level L2, the controller 9 causes the liquid replenishing device 5 to work and stop replenishing the storage tank 10 with the processing liquid. Thus, in the storage tank 10, each time the liquid level of the processing liquid is lowered to the lower limit level L1, the liquid level of the processing liquid rises to the prescribed level L2. Further, the controller 9 controls the work state of the pump 11. In the present embodiment, the controller 9 controls the pump 11 such that the pump 11 works with a constant output.

The controller 9 receives a temperature signal output from the thermal sensor 13. Thus, the controller 9 controls the temperature adjuster 12 based on a detection result of the thermal sensor 13 and the processing liquid information. Specifically, the controller 9 executes feedback control on the temperature adjuster 12 such that the detection result of the thermal sensor 13 is brought close to the target temperature.

Further, based on the processing liquid information, the controller 9 adjusts the opening of the adjusting valve 15 to the target branch opening in a period during which the power of the substrate processing apparatus 1 is turned on. Further, the controller 9 controls the plurality of chambers 4 of the substrate processing section 3 to process a plurality of substrates W using the processing liquid.

The display 81 displays an input screen for input of the processing liquid information, for example. The user can input desired processing liquid information by operating the operation unit 82 while referring to the input screen displayed on the display 81. When various information pieces are input, the controller 9 stores the input information pieces in the storage device 94. Alternatively, the controller 9 updates the information stored in the storage device 94 with the input information pieces. In a case in which the processing liquid information is stored in advance in the storage device 94 and the processing liquid information does not need to be updated, the display 81 and the operation unit 82 do not have to be provided in the substrate processing apparatus 1.

### 5. Liquid Supply Process

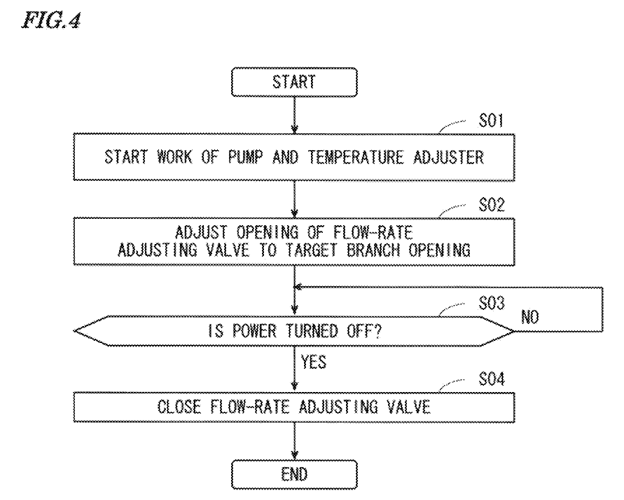

FIG. 4 is a flowchart showing one example of a liquid supply process executed in the substrate processing apparatus 1 according to the one embodiment. The below-mentioned liquid supply process is executed in a case in which the CPU 91 of the controller 9 executes the liquid supply program stored in the storage device 94 while utilizing the RAM 92 as a work area.

The liquid supply process is started when the power of the substrate processing apparatus 1 is turned on. When the liquid supply process is started, the CPU 91 starts the work of the pump 11 and the temperature adjuster 12 (step S01). Thus, the processing liquid in the storage tank 10 flows through the circulation pipe p12, and circulates between the inside of the storage tank 10 and the outside of the storage tank 10. Further, the temperature of the circulating processing liquid is brought close to the predetermined target temperature by the temperature adjuster 12.

Next, the CPU 91 adjusts the opening of the adjusting valve 15 provided in the branch pipe p40 to the predetermined target branch opening (step S02). Thus, part of the processing liquid flowing through the circulation pipe p12 flows to a portion of the chamber collection pipe p30 (main collection pipe p31) through the branch pipe p40.

Next, the CPU 91 determines whether the power of the substrate processing apparatus 1 is turned off (step S03). This determination can be made when the CPU 91 monitors various instructions input to the operation unit 82 or monitors whether the power button of the substrate processing apparatus 1 is operated.

In a case in which the power of the substrate processing apparatus 1 is not turned off, the CPU 91 repeats the process of the step S03. On the other hand, in a case in which the power of the substrate processing apparatus 1 is turned off, the CPU 91 closes the adjusting valve 15 (step S04) and ends the liquid supply process. In this case, the power supply to the pump 11 and the temperature adjuster 12 is cut off, and thus the work of the pump 11 and the work of the temperature adjuster 12 are also stopped.

Note that, in a period during which the power of the substrate processing apparatus 1 is turned on, the processing liquid replenishing function of the processing liquid supply device 2 continuously works based on the processing liquid information (the set lower limit level L1 and the set prescribed level L2) regardless of the above-mentioned liquid supply process.

### 6. Effects

(a) In the above-mentioned substrate processing apparatus 1, the processing liquid flows through the circulation pipe p12 in a period during which the power of the substrate processing apparatus 1 is turned on. Thus, the processing liquid in the storage tank 10 circulates between the inside of the storage tank 10 and the outside of the storage tank 10. The temperature of the circulating processing liquid is maintained at the target temperature or brought close to the target temperature by the temperature adjuster 12. Part of the processing liquid flowing through the circulation pipe p12 is guided to the plurality of chambers 4 through the plurality of chamber supply pipes p21. In each chamber 4, the process using the processing liquid is executed.

At least part of the processing liquid used in each chamber 4 is returned to the storage tank 10 through the chamber collection pipe p30. In the chamber 4, the processing liquid is exposed to a temperature environment of room temperature, for example. Therefore, the temperature of the processing liquid flowing into the chamber collection pipe p30 from the chamber 4 is likely to largely deviate from the target temperature. When the processing liquid having a temperature largely deviating from the target temperature is returned to the storage tank 10, the temperature of the entire processing liquid flowing through the storage tank 10 and the circulation pipe p12 may also largely deviate from the target temperature.

In contrast, with the configuration of the substrate processing apparatus 1 of FIG. 1, part of the processing liquid flowing through the circulation pipe p12 is guided to the main collection pipe p31 of the chamber collection pipe p30 through the branch pipe p40. In this case, the temperatures of the branch pipe p40 and the main collection pipe p31 can be maintained at the target temperature or a temperature close to the target temperature by the processing liquid flowing from the circulation pipe p12 to the branch pipe p40 and the main collection pipe p31. Thus, generation of particles caused by variations in temperature of the branch pipe p40 and the main collection pipe p31 can be prevented.

Further, in a case in which the processing liquid flows from the chamber 4 to the sub-collection pipe p32, the processing liquid flowing from the branch pipe p40 and the processing liquid flowing from the sub-collection pipe p32 are mixed in the main collection pipe p31. Thus, the temperature of the processing liquid used in the process for the substrate W is brought close to the target temperature. This suppresses a large deviation of the temperature of the processing liquid returned from the chamber collection pipe p30 to the tank from the target temperature. That is, the temperature of the processing liquid circulating through the processing liquid supply device 2 is maintained at the target temperature or a temperature close to the target temperature.

Further, the storage tank 10 is provided below the plurality of chambers 4. Further, in the branch pipe p40, the opening of the adjusting valve 15 is adjusted to the target branch opening, and thus the flow rate of the processing liquid flowing through the branch pipe p40 is adjusted. As described above, the target branch opening is defined such that all portions of the main collection pipe p31 are not filled with the processing liquid even in a case in which the processing liquid is collected from all of the chambers 4 of the substrate processing section 3 at the same time. Thus, the inside of the main collection pipe p31 is not filled with the processing liquid.

In this case, because an excessive amount of the processing liquid does not flow to the main collection pipe p31, the processing liquid in the main collection pipe p31 is prevented from flowing into the plurality of chambers 4 through the plurality of sub-collection pipes p32. That is, the processing liquid in the chamber collection pipe p30 is prevented from flowing backwardly. Therefore, deterioration of the processing liquid caused by a backflow of the processing liquid is also prevented. As a result, it improves credibility of the processing liquid supplied to each chamber 4.

Further, as described above, in a case in which the opening of the adjusting valve 15 is adjusted to the target branch opening, it is not necessary to consider an occurrence of a backflow of the processing liquid. Therefore, it is not necessary to provide a large difference between the height position of the plurality of chambers 4 and the height position of the storage tank 10 in order to form a smooth flow of the processing liquid using gravity. Thus, the substrate processing apparatus 1 can be made compact.

(b) In the above-mentioned substrate processing apparatus 1, the temperature adjuster 12 is provided in the circulation pipe p12. In this case, the temperature of the processing liquid flowing through the circulation pipe p12 is adjusted by the temperature adjuster 12. Thus, the processing liquid having the target temperature or a temperature close to the target temperature flows through the storage tank 10 and the circulation pipe p12. This prevents the temperature-adjusted processing liquid from staying. As a result, the temperature of the entire processing liquid in the storage tank 10 and the circulation pipe p12 can be efficiently adjusted.

(c) In the above-mentioned circulation pipe p12, the plurality of portions (c01, c02, c03) for supplying the processing liquid to the plurality of chambers 4 are located upstream of the fourth portion c04 for supplying the processing liquid to the chamber collection pipe p30. Thus, the plurality of portions (c01, c02, c03) for supplying the processing liquid to the plurality of chambers 4 are less likely to be affected by a pressure drop caused by a flow of the processing liquid from the circulation pipe p12 to the branch pipe p40. Therefore, with the configuration of the processing liquid supply device 2, the supply pressure at which the processing liquid is supplied to the plurality of chambers 4 is easily ensured.

(d) In the above-mentioned chamber collection pipe p30, the plurality of sub-collection pipes p32 are connected to the plurality of portions (c11, c12, c13) of the main collection pipe p31. Further, the branch pipe p40 is connected to the first portion c11 located at the upper end of the main collection pipe p31. In this case, the temperature of the entire collection flow path (the main collection pipe p31) that is commonly used for the plurality of chambers 4 is efficiently adjusted by the circulating processing liquid.

### 7. Substrate Processing System Including Plurality of Substrate Processing Apparatuses 1

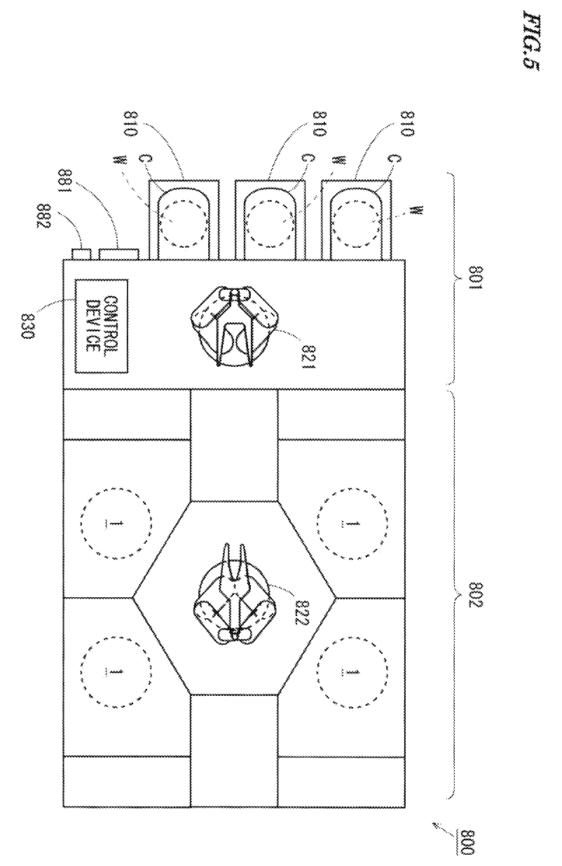

FIG. 5 is a schematic plan view showing one example of a substrate processing system including the plurality of substrate processing apparatuses 1 of FIG. 1. As shown in FIG. 5, the substrate processing system 800 of the present example includes a substrate carry-in carry-out block 801 and a substrate processing block 802.

In the substrate carry-in carry-out section 801, a plurality (three in the present example) of carrier platforms 810, a transport robot 821 and a control device 830 are provided. In each carrier platform 810, a carrier C for storing a plurality of substrates W is placed. The transport robot 821 includes a plurality (four, for example) of hands, and is configured to be capable of holding and transporting a substrate W. The control device 830 includes a CPU and a memory, or a microcomputer, and controls each constituent element of the substrate processing system 800. A display 881 and an operation unit 882 are provided in part of the outer wall of the substrate carry-in carry-out block 801.

In the substrate processing block 802, a transport robot 822 and a plurality (four in the present example) of substrate processing apparatuses 1 are provided. In plan view, the four substrate processing apparatuses 1 are arranged so as to surround the transport robot 822. Each of these substrate processing apparatuses 1 has the structure excluding the controller 9, the display 81 and the operation unit 82 of the substrate processing apparatus 1 of FIG. 1. The transport robot 822 includes a plurality (four, for example) of hands, and is configured to be capable of holding and transporting a substrate W.

In the substrate processing system 800, the control device 830 controls the work of the four substrate processing apparatuses 1 of the substrate processing block 802 as the controller 9 of FIG. 1. Further, the display 881 and the operation unit 882 are used as the common configuration among the four substrate processing apparatuses 1.

During work of the substrate processing system 800, the transport robot 821 takes out an unprocessed substrate W from any one of the plurality of carriers C placed on the plurality of carrier platforms 810, and transfers the unprocessed substrate W to the transport robot 822. The transport robot 822 transfers the received substrate W to one of the plurality of substrate processing apparatuses 1. Thus, the substrate W is processed using the processing liquid in any one of the plurality of chambers 4 included in the one substrate processing apparatus 1.

Further, the transport robot 822 takes out the processed substrate W from the one substrate processing apparatus 1 and transfers the processed substrate W to the transport robot 821. The transport robot 821 receives the processed substrate W and accommodates the substrate W in an empty carrier C.

With each substrate processing apparatus 1, the substrate W is processed using the processing liquid having high credibility. Therefore, the substrate can be processed with high efficiency and high yield.

### 8. Other Embodiments

(a) In the substrate processing apparatus 1 according to the above-mentioned embodiment, the processing liquid supply device 2 is provided in the lower region of the clean room CL, and the substrate processing section 3 is provided in the upper region of the clean room CL. However, the present disclosure is not limited to this.

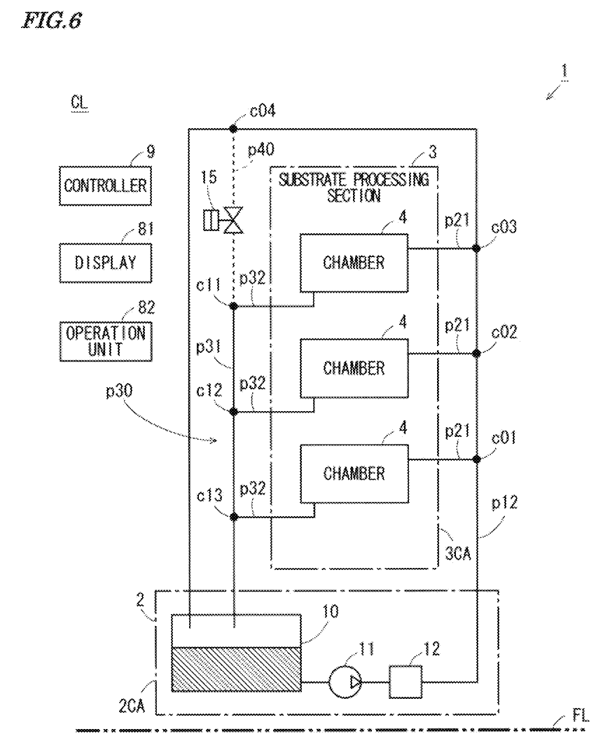

FIG. 6 is a diagram showing a first configuration example of a substrate processing apparatus 1 according to another embodiment. The differences of the substrate processing apparatus 1 of FIG. 6 from the substrate processing apparatus 1 of FIG. 1 will be described. In FIG. 6 and the subsequent drawings, main parts for describing the differences between the substrate processing apparatus 1 according to the other embodiment and the substrate processing apparatus 1 of FIG. 1 are mainly shown. Therefore, in these diagrams, a liquid replenishing device 5, a thermal sensor 13, a filter 14 and the like are suitably not shown.

In the substrate processing apparatus 1 of FIG. 6, a processing liquid supply device 2 is provided on a floor portion FL. Further, a substrate processing section 3 is stacked on the processing liquid supply device 2. In this manner, in a case in which both of the processing liquid supply device 2 and the substrate processing section 3 are provided in the upper region of a clean room CL, the floor portion FL is not present between the processing liquid supply device 2 and the substrate processing section 3. Therefore, the difference between the height position of a plurality of chambers 4 and the height position of a storage tank 10 can be made smaller than that of the example of FIG. 1. Thus, the substrate processing apparatus 1 can be made further compact.

Because an adjusting valve 15 also adjusts the flow rate of a processing liquid flowing through a chamber collection pipe p30 in the present example, a backflow of the processing liquid does not occur in the chamber collection pipe p30.

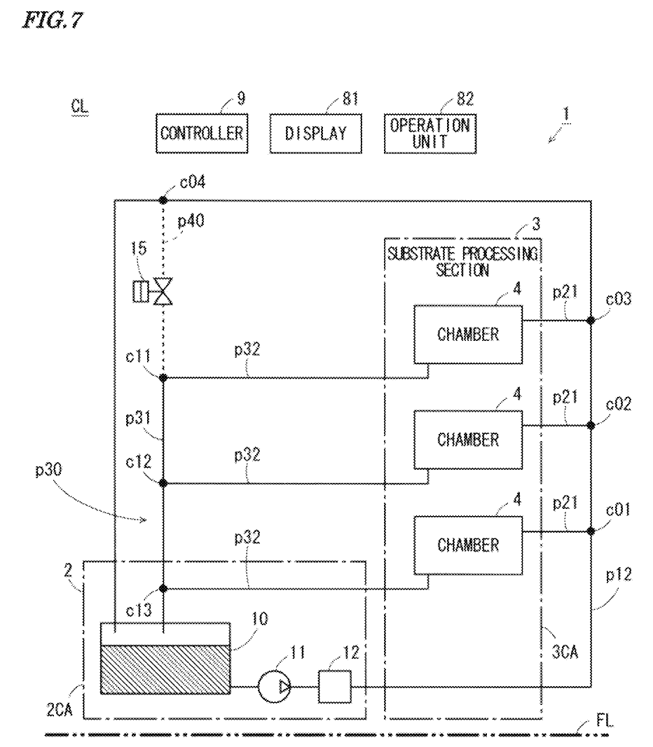

FIG. 7 is a diagram showing a second configuration example of a substrate processing apparatus 1 according to another embodiment. The differences of the substrate processing apparatus 1 of FIG. 7 from the substrate processing apparatus 1 of FIG. 1 will be described. In the substrate processing apparatus 1 of FIG. 7, a processing liquid supply device 2 is provided on a floor portion FL. That is, both of the processing liquid supply device 2 and a substrate processing section 3 are provided in the upper region of a clean room CL. Further, the processing liquid supply device 2 and the substrate processing section 3 are arranged to be adjacent to each other on the floor portion FL. Therefore, the substrate processing apparatus 1 of FIG. 7 can make the difference between the height position of a plurality of chambers 4 and the height position of a storage tank 10 be smaller than that of the example of FIG. 1. As a result, the substrate processing apparatus 1 is made further compact.

In particular, because the processing liquid supply device 2 and the substrate processing section 3 are not stacked in the substrate processing apparatus 1 of the present example, the size of the substrate processing apparatus 1 in a height direction is reduced as compared with that of the substrate processing apparatus 1 of FIG. 6.

Because an adjusting valve 15 also adjusts the flow rate of a processing liquid flowing through a chamber collection pipe p30 in the present example, a backflow of the processing liquid does not occur in the chamber collection pipe p30.

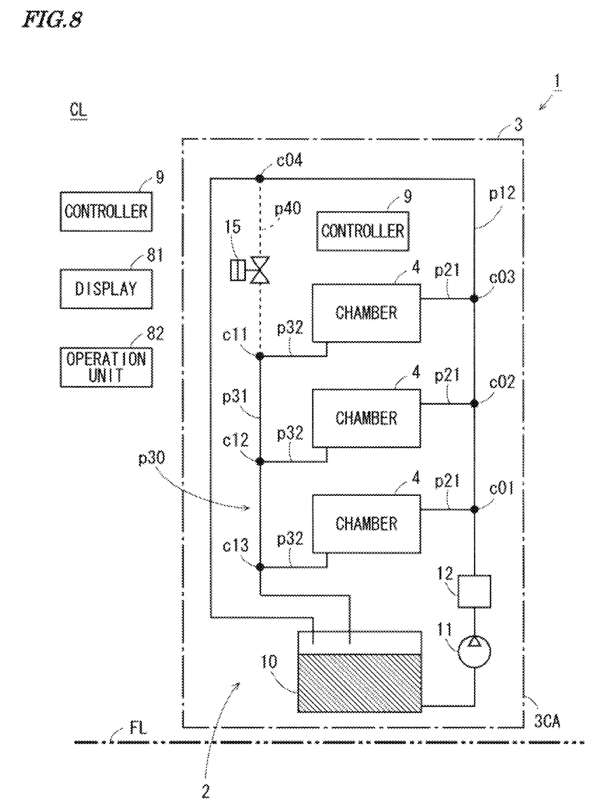

FIG. 8 is a diagram showing a third configuration example of a substrate processing apparatus 1 according to another embodiment. The differences of the substrate processing apparatus 1 of FIG. 8 from the substrate processing apparatus 1 of FIG. 1 will be described. In the substrate processing apparatus 1 of FIG. 8, a processing liquid supply device 2 does not have a supply device casing 2CA.

The constituent elements of the processing liquid supply device 2 of FIG. 1 except for the supply device casing 2CA are accommodated in a processing section casing 3CA of a substrate processing section 3. Therefore, in the substrate processing apparatus 1 of the present example, similarly to the substrate processing apparatus 1 of each of FIGS. 6 and 7, both of the processing liquid supply device 2 and the substrate processing section 3 are provided in the upper region of a clean room CL.

Further, in the processing section casing 3CA, a storage tank 10 is arranged at a position in the vicinity of a floor portion FL. Further, a plurality of chambers 4 are stacked on a storage tank 10. Therefore, the substrate processing apparatus 1 of FIG. 8 can make the difference between the height position of the plurality of chambers 4 and the height position of the storage tank 10 be smaller than that of the example of FIG. 1. As a result, the substrate processing apparatus 1 is made further compact.

Because an adjusting valve 15 also adjusts the flow rate of a processing liquid flowing through a chamber collection pipe p30 in the present example, a backflow of the processing liquid does not occur in the chamber collection pipe p30.

(b) In the substrate processing apparatus 1 according to the above-mentioned embodiment, only one chamber 4 may be provided in the substrate processing section 3, or only two chambers 4 may be provided in the substrate processing section 3. Alternatively, four or more chambers 4 may be provided in the substrate processing section 3.

(c) In the substrate processing system 800 of FIG. 5, the plurality of substrate processing apparatuses 1 may be configured to have one processing liquid supply device 2 to be commonly used with respect to the plurality of substrate processing sections 3. For example, two substrate processing apparatuses 1 may be configured such that one processing liquid supply device 2 supplies the processing liquid to the two substrate processing sections 3. Further, the four substrate processing apparatuses 1 may be configured such that one processing liquid supply device 2 supplies the processing liquid to the four substrate processing sections 3.

(d) While the opening of the adjusting valve 15 is adjusted to the preset target branch opening when the power is in the ON state in the substrate processing apparatus 1 according to the above-mentioned embodiment, the present disclosure is not limited to this.

The flow rate of the processing liquid flowing through the branch pipe p40 downstream of the adjusting valve 15 is defined by a pressure of the processing liquid in the fourth portion c04 of the chamber supply pipe p21, an opening of the adjusting valve 15 and the like. As such, a menometer may be provided in the branch pipe p40 at a position upstream of the adjusting valve 15. Alternatively, a flowmeter may be provided in the branch pipe p40 at a position upstream of the adjusting valve 15. Then, by executing feedback control of the opening of the adjusting valve 15 based on a detection result of the menometer or the flowmeter, the controller 9 may adjust the flow rate of the processing liquid such that the main collection pipe p31 is not filled with the processing liquid.

Alternatively, in the substrate processing apparatus 1, the structure (an orifice or the like) that locally reduces the flow-path area of the branch pipe p40 may be provided in the branch pipe p40 instead of the adjusting valve 15.

(e) The chamber collection pipe p30 according to the above-mentioned embodiment includes the main collection pipe p31 and the plurality of sub-collection pipes p32. Further, the upper end portion of the main collection pipe p31 is the first portion c11 of the main collection pipe p31. Further, the sub-collection pipe p32 and the branch pipe p40 are connected to the first portion c11 of the main collection pipe p31. However, the present closure is not limited to the above-mentioned example.

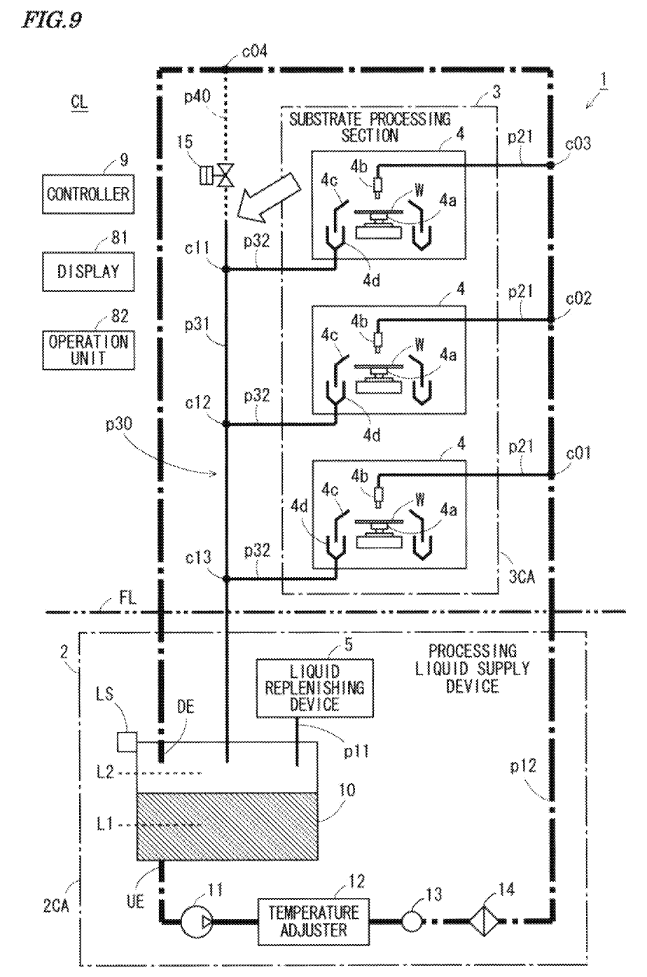

In the main collection pipe p31, the first portion c11 may be located below the upper end portion of the main collection pipe p31. FIG. 9 is a diagram for explaining one example of the configuration of a chamber collection pipe p30 according to another embodiment. As indicated by the outlined arrow in FIG. 9, in the chamber collection pipe p30 of the present example, a first portion c11 of a main collection pipe c31 is located below the upper end portion of the main collection pipe p31. In addition, a sub-collection pipe p32 is connected to the first portion c11 of the main collection pipe p31, and a branch pipe p40 is connected to the upper end portion of the main collection pipe p31.

With such a configuration, similarly to the substrate processing apparatus 1 of FIG. 1, the processing liquid flows through the branch pipe p40 to the main collection pipe p31. Thus, the temperature of the entire main collection pipe p31 is adjusted by the processing liquid.

(f) While the temperature adjuster 12 is provided in the circulation pipe p12 in the substrate processing apparatus 1 according to the above-mentioned embodiment, the present disclosure is not limited to this. The temperature adjuster 12 may be provided in the storage tank 10.

(g) While the processing liquid supply device 2 according to the above-mentioned embodiment supplies a chemical liquid to the substrate processing section 3 as one example of the processing liquid, the present disclosure is not limited to this. The processing liquid may be a rinse liquid for rinsing the upper surface of the substrate W. That is, the processing liquid supply device 2 may be configured to be capable of supplying the rinse liquid to the substrate processing section 3. Alternatively, the processing liquid may be a replacement liquid for removing the chemical liquid remaining on the upper surface of the substrate W. That is, the processing liquid supply device 2 may be configured to be capable of supplying the replacement liquid to the substrate processing section 3.

(h) In the processing liquid supply device 2 according to the above-mentioned embodiment, each of the replenishing pipe p11, the circulation pipe p12, the plurality of chamber supply pipes p21, the main collection pipe p31, the plurality of sub-collection pipes p32 and the branch pipe p40 is only required to form the flow path of the processing liquid. Therefore, each pipe (p11, p12, p21, p31, p32, p40) according to the above-mentioned embodiment may be formed of a plurality of pipes and one or a plurality of joints.

### 9. Correspondences Between Constituent Elements in Claims and Parts in Preferred Embodiments

In the following paragraphs, non-limiting examples of correspondences between various elements recited in the claims below and those described above with respect to various preferred embodiments of the present disclosure are explained. As each of various elements recited in the claims, various other elements having configurations or functions described in the claims can be also used.

In the above-mentioned embodiment, the chamber 4 that is located at the top among the plurality of chambers 4 is an example of a first chamber, the storage tank 10 is an example of a tank, the circulation pipe p12 is an example of a circulation flow path, the temperature adjuster 12 is an example of a temperature adjuster, the chamber supply pipe p21 that is located at the top among the plurality of chamber supply pipes p21 is an example of a first chamber supply flow path, and the chamber collection pipe p30 is an example of a chamber collection flow path.

Further, the branch pipe p40 is an example of a branch flow path, the adjusting valve 15 is an example of a flow-rate adjuster, the substrate processing apparatus 1 and the substrate processing system 800 are examples of a substrate processing apparatus, the third portion c03 of the circulation pipe p12 is an example of a first circulation portion, the fourth portion c04 of the circulation pipe c12 is an example of a second circulation portion, the second portion c02 of the circulation pipe p12 is an example of a third circulation portion, and the chamber 4 that is located second from the top among the plurality of chambers 4 is an example of a second chamber 4.

Further, the chamber supply pipe p21 that is located second from the top among the plurality of chamber supply pipes p21 is an example of a second chamber supply flow path, the main collection pipe p31 is an example of a main collection flow path, the sub-collection pipe p32 that is located at the top among the plurality of sub-collection pipes p32 is an example of a first collection flow path, the sub-collection pipe p32 that is located second from the top among the plurality of sub-collection pipes p32 is an example of a second collection flow path, the first portion c11 of the main collection pipe p31 is an example of a first collection portion, the second portion c12 of the main collection pipe p31 is an example of a second collection portion, and the filter 14 is an example of a filter.

### 10. Overview of Embodiments

(Item 1) A substrate processing apparatus according to item 1 includes a first chamber that executes a process on a substrate using a processing liquid, a tank that is provided below the first chamber and stores the processing liquid, a circulation flow path that causes the processing liquid in the tank to circulate between inside of the tank and outside of the tank, a temperature adjuster that adjusts, to a predetermined target temperature, a temperature of the processing liquid that is made to circulate by the circulation flow path, a first chamber supply flow path that connects the circulation flow path to the first chamber and guides the processing liquid flowing through the circulation flow path to the first chamber, a chamber collection flow path that connects the tank to the first chamber and returns the processing liquid used in the first chamber to the tank, a branch flow path that connects the circulation flow path to the chamber collection flow path and guides the processing liquid flowing through the circulation flow path to the chamber collection flow path, and a flow-rate adjuster that is provided in the branch flow path and adjusts a flow rate of the processing liquid flowing through the branch flow path.

In the substrate processing apparatus, the processing liquid circulates between the inside of the tank and the outside of the tank by flowing through the circulation flow path. The temperature of the circulating processing liquid is adjusted to the target temperature. Part of the processing liquid flowing through the circulation flow path is guided to the first chamber through the first chamber supply flow path. In the first chamber, a process is executed using the processing liquid.

At least part of the processing liquid used in the first chamber is returned to the tank through the chamber collection flow path. In the first chamber, the processing liquid is exposed to a temperature environment of room temperature, for example. Therefore, the temperature of the processing liquid flowing into the chamber collection flow path from the first chamber is likely to largely deviate from the target temperature. When the processing liquid having a temperature largely deviating from the target temperature is returned to the tank, the temperature of the entire processing liquid flowing through the tank and the circulation flow path may also largely deviate from the target temperature.

In contrast, with the above-mentioned configuration, part of the processing liquid flowing through the circulation flow path is guided to the chamber collection flow path through the branch flow path. In this case, the temperatures of the branch flow path and the chamber collection flow path can be maintained at the target temperature or a temperature close to the target temperature by the processing liquid flowing from the circulation flow path to the branch flow path and the chamber collection flow path.

Further, in a case in which the processing liquid flows from the first chamber to the chamber collection flow path, the processing liquid flowing in from the branch flow path and the processing liquid flowing from the first chamber are mixed in the chamber collection flow path. Thus, the temperature of the processing liquid used in the process for the substrate is brought close to the target temperature. This suppresses a large deviation, from the target temperature, of the temperature of the processing liquid returned from the chamber collection flow path to the tank.

Further, the tank is provided below the first chamber. Further, in the branch flow path, the flow rate of the processing liquid flowing through the branch flow path is adjusted by the flow-rate adjuster. Thus, it is possible to adjust the flow rate of the processing liquid flowing through the chamber collection flow path. Specifically, it is possible to prevent an excessive amount of the processing liquid from flowing from the branch flow path to the chamber collection flow path. Therefore, an occurrence of a backflow of the processing liquid caused by the chamber collection flow path being filled with the processing liquid is prevented, and deterioration of the processing liquid caused by a backflow of the processing liquid is also prevented. As a result, it improves credibility of the processing liquid supplied to the chamber.

(Item 2) The substrate processing apparatus according to item 1, wherein the circulation flow path may have a first circulation portion and a second circulation portion, in the circulation flow path, the first circulation portion may be located upstream of the second circulation portion, the first chamber supply flow path may connect the first circulation portion of the circulation flow path to the first chamber, and the branch flow path may connect the second circulation portion of the circulation flow path to the chamber collection flow path.

In this case, part of the processing liquid flowing through the circulation flow path is sent from the first circulation portion to the first chamber. Further, another part of the processing liquid flowing through the circulation flow path is sent from the second circulation portion downstream of the first circulation portion to the chamber collection flow path.

With the above-mentioned configuration, because the first circulation portion is located upstream of the second circulation portion, the first circulation portion is less likely to be affected by a pressure drop caused by a flow of the processing liquid through the branch flow path. Therefore, with the above-mentioned configuration, the supply pressure at which the processing liquid is supplied to the first chamber is easily ensured.

(Item 3) The substrate processing apparatus according to item 2, wherein the circulation flow path may further have a third circulation portion located upstream of the second circulation portion, the substrate processing apparatus may further include a second chamber that is provided above the tank and executes the process on the substrate using the processing liquid, and a second chamber supply flow path that connects the third circulation portion of the circulation flow path to the second chamber and guides the processing liquid flowing through the circulation flow path to the second chamber, the chamber collection flow path may include a main collection flow path, a first collection flow path and a second collection flow path, at least part of the main collection flow path may extend in an upward-and-downward direction and is connected to the tank, at least part of the main collection flow path may have a first collection portion and a second collection portion that are downwardly arranged in this order, the branch flow path may connect the second circulation portion of the circulation flow path to the first collection portion of the main collection flow path or a portion of the main collection flow path located above the first collection portion, the first collection flow path may connect the first collection portion of the main collection flow path to the first chamber, and the second collection flow path may connect the second collection portion of the main collection flow path to the second chamber.

In this case, part of the processing liquid flowing through the circulation flow path is guided to the second chamber through the second chamber supply flow path from the third circulation portion. In the second chamber, a process is executed using the processing liquid.

Further, another part of the processing liquid flowing through the circulation flow path is sent from the second circulation portion through the branch flow path to the main collection flow path. The processing liquid entering the main collection flow path from the branch flow path flows through the first collection portion and the second collection portion before entering the tank. At least part of the processing liquid used in the first chamber is returned to the first collection portion of the main collection flow path through the first collection flow path. At least part of the processing liquid used in the second chamber is sent to the second collection portion of the main collection flow path through the second collection flow path.

With the above-mentioned configuration, because the third circulation portion is located upstream of the second circulation portion, the third circulation portion is less likely to be affected by a pressure drop caused by a flow of the processing liquid through the branch flow path. Therefore, with the above-mentioned configuration, the supply pressure at which the processing liquid is supplied to the second chamber is easily ensured.

Further, in the main collection flow path, the temperature of the used processing liquid flowing into the first collection portion and the second collection portion through the first collection flow path and the second collection flow path is adjusted by the temperature of the processing liquid flowing in from the branch flow path. This improves credibility of the processing liquid supplied to each chamber.

Further, with the above-mentioned configuration, the temperature of at least the portion of the main collection flow path from the first collection portion to the tank is adjusted by the temperature of the circulating processing liquid. Therefore, the temperature of the collection flow paththat is commonly used for the first chamber and the second chamber is efficiently adjusted over a wide range by the circulating processing liquid.

(Item 4) The substrate processing apparatus according to claim 1, wherein by adjusting a flow rate of the processing liquid flowing through the branch flow path, the flow-rate adjuster may cause the processing liquid to continuously flow from the branch flow path to the chamber collection flow path in a period during which the processing liquid flows through the circulation flow path.

In this case, in a period during which the processing liquid flows through the circulation flow path, the temperature of at least part of the chamber collection flow path is adjusted to be brought close to the target temperature by the circulating processing liquid.

(Item 5) The substrate processing apparatus according to any one of items 1 to 4, wherein by adjusting a flow rate of the processing liquid flowing through the branch flow path, the flow-rate adjuster may cause the chamber collection flow path not to be filled with the processing liquid in a period during which the processing liquid flows through the circulation flow path.

In this case, it is possible to prevent an occurrence of a backflow of the processing liquid in the chamber collection flow path. Further, with the above-mentioned configuration, because it is not necessary to consider an occurrence of a backflow of the processing liquid, it is not necessary to provide a large difference between the height position of the first chamber and the height position of the tank. Thus, the substrate processing apparatus can be made compact.

(Item 6) The substrate processing apparatus according to any one of items 1 to 5, wherein the temperature adjuster may be provided in the circulation flow path.

In this case, the temperature of the processing liquid flowing through the circulation flow path is adjusted by the temperature adjuster. Thus, the processing liquid having the target temperature or a temperature close to the target temperature flows through the tank and the circulation flow path. This prevents the temperature-adjusted processing liquid from staying. As a result, it is possible to efficiently adjust the temperature of the entire processing liquid in the tank and the circulation flow path.

(Item 7) The substrate processing apparatus according to any one of items 1 to 6, may further include a filter that is provided in the circulation flow path and causes the processing liquid to flow.

In this case, foreign matter such as precipitates included in the processing liquid flowing through the circulation flow path is captured by the filter, and the processing liquid is efficiently purified.

(Item 8) A processing liquid supply device according to item 8 that supplies a processing liquid to a chamber in which a process is executed on a substrate using the processing liquid, includes a tank that is provided below the chamber and stores the processing liquid, a circulation flow path that causes the processing liquid in the tank to circulate between inside of the tank and outside of the tank, a temperature adjuster that adjusts, to a predetermined target temperature, a temperature of the processing liquid that is made to circulate by the circulation flow path, a chamber supply flow path that connects the circulation flow path to the chamber and guides the processing liquid flowing through the circulation flow path to the chamber, a chamber collection flow path that connects the tank to the chamber and returns the processing liquid used in the chamber to the tank, a branch flow path that connects the circulation flow path to the chamber collection flow path and guides the processing liquid flowing through the circulation flow path to the chamber collection flow path, and a flow-rate adjuster that is provided in the branch flow path and adjusts a flow rate of the processing liquid flowing through the branch flow path.

In the processing liquid supply device, the processing liquid in the tank flows through the circulation flow path while the temperature of the processing liquid is adjusted to the target temperature. Part of the processing liquid flowing through the circulation flow path is guided to the chamber through the chamber supply flow path. In the chamber, a process is executed using the processing liquid.

At least part of the processing liquid used in the chamber is returned to the tank through the chamber collection flow path. In the chamber, the processing liquid is exposed to a temperature environment of room temperature, for example. Therefore, the temperature of the processing liquid flowing into the chamber collection flow path from the chamber is likely to largely deviate from the target temperature. When the processing liquid having a temperature largely deviating from the target temperature is returned to the tank, the temperature of the entire processing liquid flowing through the tank and the circulation flow path may also largely deviate from the target temperature.

In contrast, with the above-mentioned configuration, part of the processing liquid flowing through the circulation flow path is guided to the chamber collection flow path through the branch flow path. In this case, the temperatures of the branch flow path and the chamber collection flow path can be maintained at the target temperature or a temperature close to the target temperature by the processing liquid flowing from the circulation flow path to the branch flow path and the chamber collection flow path.

Further, in a case in which the processing liquid flows from the chamber to the chamber collection flow path, the processing liquid flowing in from the branch flow path and the processing liquid flowing in from the chamber are mixed in the chamber collection flow path. Thus, the temperature of the processing liquid used in the process for the substrate is brought close to the target temperature. This suppresses a large deviation, from the target temperature, of the temperature of the processing liquid returned from the chamber collection flow path to the tank.

Further, the tank is provided below the chamber. Further, in the branch flow path, the flow rate of the processing liquid flowing through the branch flow path is adjusted by the flow-rate adjuster. Thus, it is possible to adjust the flow rate of the processing liquid flowing through the chamber collection flow path. Specifically, it is possible to prevent an excessive amount of the processing liquid from flowing from the branch flow path to the chamber collection flow path. Therefore, an occurrence of a backflow of the processing liquid caused by the chamber collection flow path being filled with the processing liquid is prevented, and deterioration of the processing liquid caused by a backflow of the processing liquid is also prevented. As a result, it improves credibility of the processing liquid supplied to the chamber.

(Item 9) A substrate processing method according to item 9 of processing a substrate using a substrate processing apparatus, wherein the substrate processing apparatus further includes a chamber that executes a process on the substrate using a processing liquid, a tank that is provided below the chamber and stores the processing liquid, a circulation flow path that causes the processing liquid in the tank to circulate between inside of the tank and outside of the tank, a chamber supply flow path that connects the circulation flow path to the chamber and guides the processing liquid flowing through the circulation flow path to the chamber, and a chamber collection flow path that connects the tank to the chamber and returns the processing liquid used in the chamber to the tank, and the substrate processing method includes adjusting, to a predetermined target temperature, a temperature of the processing liquid that is made to circulate by the circulation flow path, guiding the processing liquid flowing through the circulation flow path to the chamber collection flow path using a branch flow path, the branch flow path connecting the circulation flow path to the chamber collection flow path, and adjusting a flow rate of the processing liquid flowing through the branch flow path.

With the substrate processing method, the processing liquid circulates between the inside of the tank and the outside of the tank by flowing through the circulation flow path. The temperature of the circulating processing liquid is adjusted to the target temperature. Part of the processing liquid flowing through the circulation flow path is guided to the chamber through the chamber supply flow path. In the chamber, a process is executed using the processing liquid.

At least part of the processing liquid used in the chamber is returned to the tank through the chamber collection flow path. In the chamber, the processing liquid is exposed to a temperature environment of room temperature, for example. Therefore, the temperature of the processing liquid flowing into the chamber collection flow path from the chamber is likely to largely deviate from the target temperature. When the processing liquid having a temperature largely deviating from the target temperature is returned to the tank, the temperature of the entire processing liquid flowing through the tank and the circulation flow path may also largely deviate from the target temperature.

In contrast, with the above-mentioned method, part of the processing liquid flowing through the circulation flow path is guided to the chamber collection flow path through the branch flow path. In this case, the temperatures of the branch flow path and the chamber collection flow path can be maintained at the target temperature or a temperature close to the target temperature by the processing liquid flowing from the circulation flow path to the branch flow path and the chamber collection flow path.

Further, in a case in which the processing liquid flows from the chamber to the chamber collection flow path, the processing liquid flowing in from the branch flow path and the processing liquid flowing in from the chamber are mixed in the chamber collection flow path. Thus, the temperature of the processing liquid used in the process for the substrate is brought close to the target temperature. This suppresses a large deviation, from the target temperature, of the temperature of the processing liquid returned from the chamber collection flow path to the tank.

Further, the tank is provided below the chamber. Further, in the branch flow path, the flow rate of the processing liquid flowing through the branch flow path is adjusted. Thus, it is possible to adjust the flow rate of the processing liquid flowing through the chamber collection flow path. Specifically, it is possible to prevent an excessive amount of the processing liquid from flowing from the branch flow path to the chamber collection flow path. Therefore, an occurrence of a backflow of the processing liquid caused by the chamber collection flow path being filled with the processing liquid is prevented, and deterioration of the processing liquid caused by a backflow of the processing liquid is also prevented. As a result, it improves credibility of the processing liquid supplied to the chamber.

(Item 10) A processing liquid supply method according to item 10 of supplying a processing liquid to a chamber in which a process is executed on a substrate using a processing liquid supply device, wherein the processing liquid supply device includes a tank that is provided below the chamber and stores the processing liquid, a circulation flow path that causes the processing liquid in the tank to circulate between inside of the tank and outside of the tank, a chamber supply flow path that connects the circulation flow path to the chamber and guides the processing liquid flowing through the circulation flow path to the chamber, and a chamber collection flow path that connects the tank to the chamber and returns the processing liquid used in the chamber to the tank, and the processing liquid supply method includes adjusting, to a predetermined target temperature, a temperature of the processing liquid that is made to circulate by the circulation flow path, guiding the processing liquid flowing through the circulation flow path to the chamber collection flow path using a branch flow path, the branch flow path connecting the circulation flow path to the chamber collection flow path, and adjusting a flow rate of the processing liquid flowing through the branch flow path.

With the processing liquid supply method, the processing liquid in the tank flows through the circulation flow path while the temperature of the processing liquid is adjusted to the target temperature. Part of the processing liquid flowing through the circulation flow path is guided to the chamber through the chamber supply flow path. In the chamber, a process is executed using the processing liquid.

At least part of the processing liquid used in the chamber is returned to the tank through the chamber collection flow path. In the chamber, the processing liquid is exposed to a temperature environment of room temperature, for example. Therefore, the temperature of the processing liquid flowing into the chamber collection flow path from the chamber is likely to largely deviate from the target temperature. When the processing liquid having a temperature largely deviating from the target temperature is returned to the tank, the temperature of the entire processing liquid flowing through the tank and the circulation flow path may also largely deviate from the target temperature.

In contrast, with the above-mentioned method, part of the processing liquid flowing through the circulation flow path is guided to the chamber collection flow path through the branch flow path. In this case, the temperatures of the branch flow path and the chamber collection flow path can be maintained at the target temperature or a temperature close to the target temperature by the processing liquid flowing from the circulation flow path to the branch flow path and the chamber collection flow path.

Further, in a case in which the processing liquid flows from the chamber to the chamber collection flow path, the processing liquid flowing in from the branch flow path and the processing liquid flowing in from the chamber are mixed in the chamber collection flow path. Thus, the temperature of the processing liquid used in the process for the substrate is brought close to the target temperature. This suppresses a large deviation, from the target temperature, of the temperature of the processing liquid returned from the chamber collection flow path to the tank.

Further, the tank is provided below the chamber. Further, in the branch flow path, the flow rate of the processing liquid flowing through the branch flow path is adjusted. Thus, it is possible to adjust the flow rate of the processing liquid flowing through the chamber collection flow path. Specifically, it is possible to prevent an excessive amount of the processing liquid from flowing from the branch flow path to the chamber collection flow path. Therefore, an occurrence of a backflow of the processing liquid caused by the chamber collection flow path being filled with the processing liquid is prevented, and deterioration of the processing liquid caused by a backflow of the processing liquid is also prevented. As a result, it improves credibility of the processing liquid supplied to the chamber.

While preferred embodiments of the present disclosure have been described above, it is to be understood that variations and modifications will be apparent to those skilled in the art without departing the scope and spirit of the present disclosure. The scope of the present disclosure, therefore, is to be determined solely by the following claims.

I claim:

1. A substrate processing apparatus comprising:
a first chamber that executes a process on a substrate using a processing liquid;
a tank that is provided below the first chamber and stores the processing liquid;
a circulation flow path that causes the processing liquid in the tank to circulate between inside of the tank and outside of the tank;
a temperature adjuster that adjusts, to a predetermined target temperature, a temperature of the processing liquid that is made to circulate by the circulation flow path;
a first chamber supply flow path that connects the circulation flow path to the first chamber and guides the processing liquid flowing through the circulation flow path to the first chamber;
a chamber collection flow path that connects the tank to the first chamber and returns the processing liquid used in the first chamber to the tank;
a branch flow path that connects the circulation flow path to the chamber collection flow path and guides the processing liquid flowing through the circulation flow path to the chamber collection flow path; and
a flow-rate adjuster that is provided in the branch flow path and adjusts a flow rate of the processing liquid flowing through the branch flow path.

2. The substrate processing apparatus according to claim 1, wherein
the circulation flow path has a first circulation portion and a second circulation portion,
in the circulation flow path, the first circulation portion is located upstream of the second circulation portion,
the first chamber supply flow path connects the first circulation portion of the circulation flow path to the first chamber, and
the branch flow path connects the second circulation portion of the circulation flow path to the chamber collection flow path.

3. The substrate processing apparatus according to claim 2, wherein
the circulation flow path further has a third circulation portion located upstream of the second circulation portion,
the substrate processing apparatus further includes
a second chamber that is provided above the tank and executes the process on the substrate using the processing liquid, and
a second chamber supply flow path that connects the third circulation portion of the circulation flow path to the second chamber and guides the processing liquid flowing through the circulation flow path to the second chamber,
the chamber collection flow path includes a main collection flow path, a first collection flow path and a second collection flow path,
at least part of the main collection flow path extends in an upward-and-downward direction and is connected to the tank,
at least part of the main collection flow path has a first collection portion and a second collection portion that are downwardly arranged in this order,
the branch flow path connects the second circulation portion of the circulation flow path to the first collection portion of the main collection flow path or a portion of the main collection flow path located above the first collection portion,
the first collection flow path connects the first collection portion of the main collection flow path to the first chamber, and
the second collection flow path connects the second collection portion of the main collection flow path to the second chamber.

4. The substrate processing apparatus according to claim 1, wherein
by adjusting a flow rate of the processing liquid flowing through the branch flow path, the flow-rate adjuster causes the processing liquid to continuously flow from the branch flow path to the chamber collection flow path in a period during which the processing liquid flows through the circulation flow path.

5. The substrate processing apparatus according to claim 1, wherein
by adjusting a flow rate of the processing liquid flowing through the branch flow path, the flow-rate adjuster causes the chamber collection flow path not to be filled with the processing liquid in a period during which the processing liquid flows through the circulation flow path.

6. The substrate processing apparatus according to claim 1, wherein
the temperature adjuster is provided in the circulation flow path.

7. The substrate processing apparatus according to claim 1, further comprising a filter that is provided in the circulation flow path and causes the processing liquid to flow.

8. A processing liquid supply device that supplies a processing liquid to a chamber in which a process is executed on a substrate using the processing liquid, comprising:
a tank that is provided below the chamber and stores the processing liquid;
a circulation flow path that causes the processing liquid in the tank to circulate between inside of the tank and outside of the tank;
a temperature adjuster that adjusts, to a predetermined target temperature, a temperature of the processing liquid that is made to circulate by the circulation flow path;
a chamber supply flow path that connects the circulation flow path to the chamber and guides the processing liquid flowing through the circulation flow path to the chamber;
a chamber collection flow path that connects the tank to the chamber and returns the processing liquid used in the chamber to the tank;
a branch flow path that connects the circulation flow path to the chamber collection flow path and guides the processing liquid flowing through the circulation flow path to the chamber collection flow path; and
a flow-rate adjuster that is provided in the branch flow path and adjusts a flow rate of the processing liquid flowing through the branch flow path.

9. A substrate processing method of processing a substrate using a substrate processing apparatus,
the substrate processing apparatus further comprising:
a chamber that executes a process on the substrate using a processing liquid;
a tank that is provided below the chamber and stores the processing liquid;
a circulation flow path that causes the processing liquid in the tank to circulate between inside of the tank and outside of the tank;
a chamber supply flow path that connects the circulation flow path to the chamber and guides the processing liquid flowing through the circulation flow path to the chamber; and
a chamber collection flow path that connects the tank to the chamber and returns the processing liquid used in the chamber to the tank,
the substrate processing method including:
adjusting, to a predetermined target temperature, a temperature of the processing liquid that is made to circulate by the circulation flow path;
guiding the processing liquid flowing through the circulation flow path to the chamber collection flow path using a branch flow path, the branch flow path connecting the circulation flow path to the chamber collection flow path; and
adjusting a flow rate of the processing liquid flowing through the branch flow path.

10. A processing liquid supply method of supplying a processing liquid to a chamber in which a process is executed on a substrate using a processing liquid supply device,
the processing liquid supply device comprising:
a tank that is provided below the chamber and stores the processing liquid;
a circulation flow path that causes the processing liquid in the tank to circulate between inside of the tank and outside of the tank;
a chamber supply flow path that connects the circulation flow path to the chamber and guides the processing liquid flowing through the circulation flow path to the chamber; and
a chamber collection flow path that connects the tank to the chamber and returns the processing liquid used in the chamber to the tank,
the processing liquid supply method including:
adjusting, to a predetermined target temperature, a temperature of the processing liquid that is made to circulate by the circulation flow path;
guiding the processing liquid flowing through the circulation flow path to the chamber collection flow path using a branch flow path, the branch flow path connecting the circulation flow path to the chamber collection flow path; and
adjusting a flow rate of the processing liquid flowing through the branch flow path.
